(19) United States
(12) Patent Application Publication
(10) Pub. No.: US 2026/0133402 A1
(43) Pub. Date: May 14, 2026

(54) ACTUATABLE MIRROR ASSEMBLY

(71) Applicant: Carl Zeiss SMT GmbH, Oberkochen (DE)

(72) Inventor: Markus HAUF, Ulm (DE)

(21) Appl. No.: 19/444,096

(22) Filed: Jan. 8, 2026

Related U.S. Application Data
(63) Continuation of application No. PCT/EP2024/068926, filed on Jul. 4, 2024.

(30) Foreign Application Priority Data
Jul. 13, 2023 (DE) 10 2023 206 689.0

(51) Int. Cl. G02B 7/182; G03F 7/00

(52) U.S. Cl. CPC G02B 7/182; G03F 7/70258; G03F 7/70816; G03F 7/70825; G03F 7/7085; G03F 7/70958

(57) ABSTRACT

An actuatable mirror assembly has an actuator apparatus with a main actuator unit fixed to the frame and an actuator mirror carrier unit that is displaceable by actuator vis-à-vis the main actuator unit. The mirror assembly has at least one mirror with a reflection surface secured to the actuator mirror carrier unit. A bearing device secures the mirror to the actuator mirror carrier unit. The bearing device is embodied such that an enclosed securing region of the mirror, provided by the bearing device, has an extent between maximally spaced-apart securing points of the bearing device in the direction of a maximal securing distance on the actuator mirror carrier unit, the extent being at least 15% of a typical extent of the reflection surface of the mirror. This can result in an improved actuatable mirror assembly, such as for use in projection lithography.

### CROSS-REFERENCE TO RELATED APPLICATIONS

The present application is a continuation of, and claims benefit under 35 USC 120 to, international application No. PCT/EP2024/068926, filed Jul. 7, 2024, which claims benefit under 35 USC 119 of German Application No. 10 2023 206 689.0, filed Jul. 13, 2023. The entire disclosure of each of these applications is incorporated by reference herein.

### FIELD

The disclosure relates to an actuatable mirror assembly. The disclosure also relates to a MEMS mirror apparatus having at least one such mirror assembly, an optical system having at least one such MEMS mirror apparatus, a projection exposure apparatus having such an optical system, a method for producing a microstructured or nanostructured component with the aid of such a projection exposure apparatus and a microstructured or nanostructured component produced according to such a method.

### BACKGROUND

A mirror assembly is known, for example as a field facet mirror or as a pupil facet mirror from DE 10 2021 214 237 A1. Such facet mirrors are also known in the form of micromirror apparatuses or MEMS mirror apparatuses, for example from WO 2016/146 541 A1 and from DE 10 2008 009 600 A1.

### SUMMARY

The present disclosure seeks to develop an improved actuatable mirror assembly that, such as for use in projection lithography.

In an aspect, the disclosure provides an actuatable mirror assembly having an actuator apparatus comprising a main actuator unit fixed to the frame and an actuator mirror carrier unit that is displaceable by actuator vis-à-vis the main actuator unit. The assembly also has at least one mirror with a reflection surface secured to the actuator mirror carrier unit. Further, the assembly has a bearing device for securing the mirror to the actuator mirror carrier unit. The bearing device is embodied such that an enclosed securing region of the mirror, provided by the bearing device, has an extent between maximally spaced-apart securing points of the bearing device in the direction of a maximal securing distance on the actuator mirror carrier unit. The extent is at least 15% of a typical extent of the reflection surface of the mirror.

According to the disclosure, the mirror of the actuatable mirror assembly can be secured to the actuator mirror carrier unit, which is displaceable by actuator, by way of a bearing device that does not have a small spatial extent in relation to an enclosed securing region when compared with the typical reflection surface extent of the mirror. This can help to ensure that the mirror is secured to the actuator mirror carrier unit in a mechanically stable fashion for example. For example, unwanted mirror resonances or an unwanted mirror tilt may be avoided in that case. A relatively precise, defined mirror position can be achieved on account of the extensive secured state. Furthermore, relatively good thermal coupling of the mirror to the actuator apparatus can be ensured. In that case, heat dissipated onto the mirror by absorption for example can then be dissipated well.

An enclosed securing region is formed by at least one securing track, along which the mirror is secured to the actuator mirror carrier unit, with this at least one securing track delimiting at least 50% of the enclosed securing region in the circumferential enclosing direction.

For example, this can help give rise to a desirably rigid and drift-resistant mirror assembly.

The mirror can be coupled to the actuator mirror carrier unit in mechanically stable fashion.

The typical extent of the mirror reflection surface may also be measured in the direction of the maximal securing distance, in the direction of which the extent of the enclosed securing region is specified. Alternatively, the typical extent of the mirror reflection surface may also be determined in a different way, for example as a mean value of different reflection surface extents, for example if use is made of a mirror that deviates from a circular shape and for example if use is made of a mirror with an aspect ratio not equal to 1. For example, if a rectangular mirror surface is used then the typical reflection surface extent may be the mean value of the two edge lengths of the rectangle. In the case of a round reflection surface, the typical reflection surface extent corresponds to the reflection surface diameter. The extent of the enclosed securing region in the direction of the maximal securing distance may be at least 20%, may be at least 25%, may be at least 30%, may be at least 40% and may be at least 50% of the typical reflection surface extent, and it may be even larger than that. The extent of the enclosed securing region in the direction of the maximal securing distance is regularly smaller than the typical extent of the mirror reflection surface.

The actuator apparatus may comprise at least one actuator transducer on the actuator mirror carrier unit and at least one actuator transducer on the main actuator unit. The respective actuator transducer is an example of an actuator device of the actuator apparatus. Multiple such actuator transducers per actuator unit are also possible.

The mirror on the one hand and the actuator mirror carrier unit on the other may be connected or adhesively bonded to the bearing device for securing purposes via a bonding method such as adhesive bonding, eutectic bonding, diffusion bonding, welding or solder bonding. The bearing device may be connected in one piece to the actuator mirror carrier unit and may for example be integrally formed thereon. The bearing device may be connected in one piece to a mirror body of the mirror. The bearing device may be connected in one piece to the actuator mirror carrier unit, for example to a support plate of the actuator mirror carrier unit. Alternatively, the bearing device may also be embodied as a component which is separate from the mirror body and/or the actuator mirror carrier unit and which is connected to the mirror body and/or the actuator mirror carrier unit.

The actuator apparatus may include at least one tilt device for tilting the actuator mirror carrier unit. Multiple tilt devices of this type may also be provided.

For example, the mirror assembly may have been created with the aid of MEMS manufacturing technologies, for example via lithographic structuring of layers and/or by bonding processes.

An assembly can have a sensor device having a main sensor component secured to the main actuator unit and a sensor mirror carrier component secured to the actuator mirror carrier unit, wherein at least one of the securing points is arranged directly adjacent to the sensor mirror carrier component. Such a sensor device help ensure a relatively precise detection of a pose of the mirror relative to the main actuator unit since forces imparted via the bearing device on the actuator mirror carrier unit on account of the displacement of the mirror are transmitted directly and for example without falsifying tilt moments to the actuator mirror carrier unit and hence also to the components of the sensor apparatus, specifically the sensor mirror carrier component, the displacement of which relative to the main sensor component can then be detected with great precision.

A normal to the reflection surface of the mirror that passes through the at least one securing point directly adjacent to the sensor mirror carrier component may also pass through the sensor mirror carrier component.

The respective securing point is directly adjacent to the sensor mirror carrier component if e.g. the distance between the securing point and the sensor mirror carrier component is no more than 1.5 times the thickness of an intermediate support plate, which may be a constituent part of the actuator mirror carrier unit.

The enclosed securing region can comprise a circumferential securing track. Such a circumferential securing track can lead to a further increase in stability since a correspondingly circumferential bearing track of the bearing device is present. The enclosed securing region may be designed as a securing ring in that case. An extent of the enclosed securing region in the direction of the maximal securing distance is given by the ring diameter in the case of a circular fixing ring. The circumferential securing track may also have an elliptical design or else a predetermined polygonal design. The enclosed securing region may comprise multiple nested securing tracks, which are circumferential for example. Such securing tracks may have a concentric arrangement.

A securing track as a whole can be arranged directly adjacent to the sensor mirror carrier component. Such an arrangement of the securing track can lead to the possibility of detecting a displacement of the mirror relative to the main actuator unit particularly precisely by a sensor mechanism. This renders exact positioning of the mirror possible.

The enclosed securing region can comprise at least two spaced-apart securing tracks. Such multiple spaced-apart securing tracks may help ensure that the mirror is stably secured to the actuator mirror carrier unit. The enclosed securing region may have exactly two spaced-apart securing tracks. These securing tracks can delimit at least 50% of the enclosed securing region. For example, if two securing tracks of length L are present, which are spaced apart from one another by a distance A and extend radially and parallel to each other in this example, then the following applies: L≥A.

At least one or all of the spaced-apart securing tracks can be designed as straight securing tracks. At least one straight securing track may be well adapted to a symmetry of the mirror assembly.

The spaced-apart securing tracks can extend parallel to one another. This may be well adapted to a symmetry of the mirror assembly.

The securing track can have a transverse extent transversely to the extent of the track that is less than 10% of a longitudinal extent in the direction of extent of the track of the securing track. This can lead to a small influence on a figure of the reflection surface on account of bearing-side force influences on the mirror. The longitudinal extent in the direction of the extent of the track of the securing track, to which the transverse extent is related, is given by the circular circumference in the case of a circular securing track.

The extent of the enclosed securing region in the direction of the maximal securing distance can correspond to a distance between two actuator devices of the actuator apparatus. This can lead to an introduction of forces which does not influence the mirror much when the mirror carrier unit is displaced by an actuation mechanism. The extent of the enclosed securing region in the direction of the maximal securing distance in that case corresponds to the distance between the two actuator devices if these two parameters do not differ from each other by more than 30%, by more than 20% or by more than 10%.

The reflection surface of the mirror can be concave or convex with respect to the direction of curvature and a spherical or toric embodiment or cylindrical with respect to the shape of curvature. Such reflection surface designs have proven successful when using the mirror assembly within an illumination optics unit of a projection exposure apparatus for example. The mirror reflection surface may also be designed as a plane surface. An extent and/or track profiles of the securing tracks predetermined by the respective bearing device may be adapted to respective curvature profiles of the reflection surface of the mirror in the mirror assembly.

A mirror body of the mirror can have a stress coating for generating a curvature of or a curvature profile for the reflection surface. In order to specify such a curvature profile of the reflection surface, use can be made of a stress coating on a mirror body of the mirror, the former for example exerting a tensile stress on the reflection surface for the concave embodiment of the mirror. The stress coating may be located above or below an optionally additionally provided optical coating of the reflection surface.

In principle, such a stress coating is known from DE 10 2014 201 622 A1.

The bearing device can help allow the mirror to be mounted in such a way that the desired curvature profile arises as a result of the layer stress in the stress coating.

Examples of a predefinable curvature profile include a spherical curvature profile, an aspherical curvature profile or else a toric curvature profile.

An underside of a mirror body of the mirror, i.e. a side facing away from the reflection surface, may be contoured or structured in order to specify the curvature profile. Appropriate contouring/structuring may be formed by a plurality of grooves, the profile of which is adapted to a symmetry of a predefined curvature profile of the reflection surface. For example, to the extent that the reflection surface should be shaped as a cylindrical surface, corresponding mirror body contours or structures may have a straight embodiment. Should a rotationally symmetrical curvature of the reflection surface be desired, e.g. a concave or convex curvature, corresponding contouring/structuring may be formed by concentric structures for example.

A mirror body of the mirror may be manufactured from silicon. One material variant of the mirror body may be a material with an anisotropic Young's modulus, and this may be used for the targeted specification of a desired curvature profile of the reflection surface of the mirror.

The features of the mirror assembly come to bear particularly well when the mirror assembly is used within a MEMS mirror apparatus. The MEMS mirror apparatus may comprise several 10, several 100 or else several 1000 such mirror assemblies. The MEMS mirror apparatus might be a field facet mirror of an illumination optics unit in a microlithographic projection exposure apparatus. In an alternative to that or in addition, the MEMS mirror apparatus may form a pupil facet mirror of such an illumination optics unit. It is also possible to implement a facet relay mirror of a specular reflector, which is at a distance from a pupil plane of the illumination optics unit, as such a MEMS mirror apparatus.

The features of related optical systems, projection exposure apparatuses, production methods and produced components can correspond to explained above with reference to the mirror assembly and with reference to a MEMS mirror apparatus. The optical system can be an illumination optics unit and/or a projection optics unit of the projection exposure apparatus. The projection exposure apparatus may comprise an EUV light source or else a DUV light source.

The produced component can be a microchip, for example a memory chip.

### BRIEF DESCRIPTION OF THE DRAWINGS

At least one exemplary embodiment of the disclosure is described hereinafter with reference to the drawings, in which:

FIG. 1 schematically shows a meridional section of a projection exposure apparatus for EUV projection lithography;

FIG. 2 shows, in much enlarged fashion and in a perspective view, an axial section through an actuatable mirror assembly of an individual mirror in a facet mirror of an illumination optics unit in the projection exposure apparatus according to FIG. 1;

FIG. 3 shows, in a perspective sectional view similar to FIG. 2, the mirror assembly according to FIG. 2 having a mount for a mirror body of an individual mirror of the assembly, the mount being exposed in one quadrant for illustration purposes;

FIG. 4 shows, in an illustration according to FIG. 2, an elucidation of force and position transfer between the mirror body and an actuator mirror carrier unit of the assembly by way of the mirror body mounting;

FIG. 5 shows, once again in an illustration corresponding to FIG. 2, exemplary heat conduction paths from a reflection surface of the mirror via the actuator mirror carrier unit to a main actuator unit, fixed with respect to the frame, of the assembly, once again by way of the mirror body mounting;

FIG. 6A shows, in greatly exaggerated fashion, an effect of a stress coating on the mirror for the purpose of specifying a curvature profile of the reflection surface in the case of a “spherical curvature profile” design;

FIG. 6B shows a plan view of the mirror in accordance with the viewing direction VI A in FIG. 6A;

FIG. 7 shows a mirror having a mirror body and an actuator mirror carrier unit in a further embodiment of a mirror assembly, which may be used instead of the mirror assembly according to FIG. 2; and

FIG. 8 shows, in an illustration obliquely from below, the assembly according to FIG. 7 with a toric mirror surface (cylindrical mirror surface) generated on the mirror via a stress coating.

### DETAILED DESCRIPTION

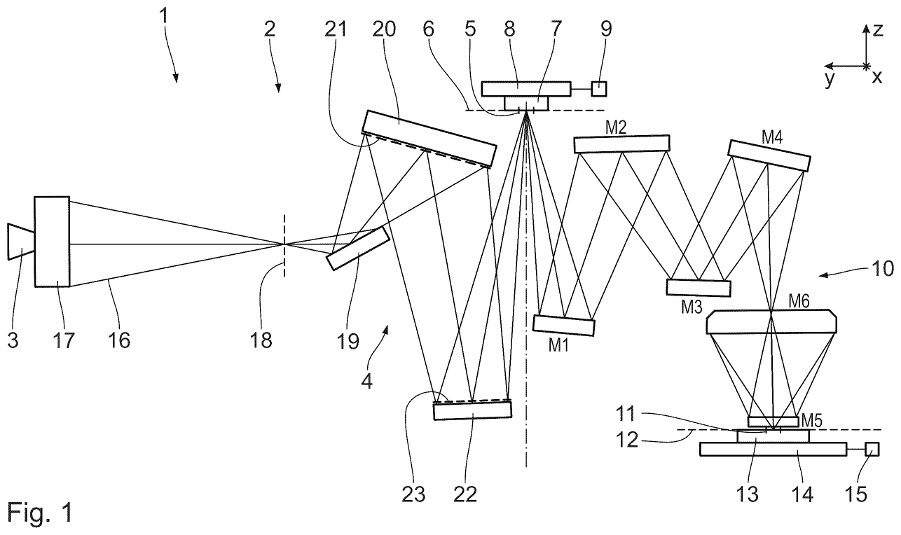

Certain component parts of a microlithographic projection exposure apparatus 1 are described in exemplary fashion below, initially with reference to FIG. 1. The description of the basic setup of the projection exposure apparatus 1 and its components should not be construed as limiting here.

One embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided as a module separate from the rest of the illumination system. In this case, the illumination system does not comprise the light source 3.

An object which is in the form of a reticle 7 and arranged in the object field 5 is exposed. The reticle 7 is held by a reticle holder 8. The reticle holder 8 is displaceable for example in a scanning direction by way of a reticle displacement drive 9.

In FIG. 1, a Cartesian xyz-coordinate system is drawn in for elucidation. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a substrate in the form of a wafer 13 arranged in the region of the image field 11 in the image plane 12. The wafer 13 is held by a wafer holder 14. The wafer holder 14 is displaceable by way of a wafer displacement drive 15 for example in the y-direction. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits for example EUV radiation 16, which is also referred to below as used radiation, illumination radiation or illumination light. The used radiation has for example a wavelength in the range between 5 nm and 30 nm. The radiation source 3 may be a plasma source, for example a laser-produced plasma (LPP) source or a gas discharge-produced plasma (GDPP) source. It may also be a synchrotron-based radiation source. The radiation source 3 may be a free electron laser (FEL).

The illumination radiation 16 emanating from the radiation source 3 is focused by a collector 17. The collector 17 may be a collector having one or more ellipsoidal and/or hyperboloid reflection faces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may constitute a separation between a radiation source module, comprising the radiation source 3 and the collector 17, and the illumination optics unit 4.

The illumination optics unit 4 comprises a deflection mirror 19 and, disposed downstream thereof in the beam path, a first facet mirror 20. The deflection mirror 19 may be a plane deflection mirror or alternatively a mirror with a beam-influencing effect going beyond the pure deflection effect. In an alternative to that or in addition, the deflection mirror 19 may take the form of a spectral filter that separates a used light wavelength of the illumination radiation 16 from extraneous light of a wavelength differing therefrom. If the first facet mirror 20 is arranged in a plane of the illumination optics unit 4 which is optically conjugate to the object plane 6 as a field plane, it is also referred to as a field facet mirror. The first facet mirror 20 comprises a multiplicity of individual first facets 21, which are also referred to below as field facets. Only some of these facets 21 are shown in FIG. 1 by way of example.

The first facets 21 are embodied as rectangular facets or as facets with an arcuate or partly circular edge contour. The first facets 21 may be embodied as plane facets or alternatively as convexly or concavely curved facets.

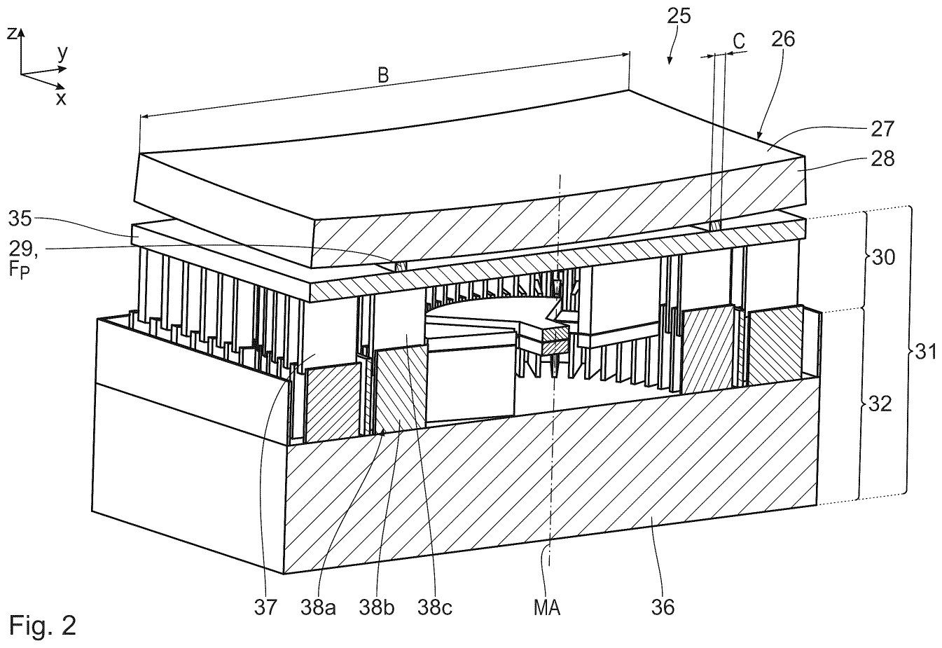

As known for example from DE 10 2008 009 600 A1, the first facets 21 themselves may be composed in each case of a plurality or multiplicity of individual mirrors, for example a multiplicity of micromirrors. A mirror assembly having such an individual mirror will be explained in detail below of the basis of FIG. 2 et seq. In that case, the plurality or multiplicity of the individual mirrors each form one of the first facets 21, wherein the individual mirrors may have a correspondingly convexly or concavely curved embodiment.

The first facet mirror 20 is in the form of a microelectromechanical system (MEMS system). For details, reference is made to e.g. DE 10 2008 009 600 A1.

The illumination radiation 16 travels horizontally, i.e. in the y-direction, between the collector 17 and the deflection mirror 19.

In the beam path of the illumination optics unit 4, a second facet mirror 22 is arranged downstream of the first facet mirror 20. Should the second facet mirror 22 be arranged in a pupil plane of the illumination optics unit 4, it is also referred to as a pupil facet mirror. The second facet mirror 22 may also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of individual mirrors or micromirrors. In this regard, reference is likewise made to DE 10 2008 009 600 A1. To the extent that the second facets 23 are also composed of a plurality or multiplicity of individual mirrors in each case, the second facet mirror 22 may take the form of a MEMS system corresponding to the first facet mirror 20.

The second facets 23 and optionally the individual mirrors constructed therefrom may have planar or, alternatively, convexly or concavely curved reflection surfaces.

The illumination optics unit 4 may form a doubly faceted system. This basic principle is also referred to as a fly's eye condenser (fly's eye integrator).

It may be desirable to arrange the second facet mirror 22 not exactly in a plane that is optically conjugate to a pupil plane of the projection optics unit 10. For example, the pupil facet mirror 22 may be arranged at a tilt with respect to a pupil plane in the projection optics unit 10, for example as described in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not depicted here) of the illumination optics unit 4, a transfer optics unit contributing for example to the imaging of the first facets 21 into the object field 5 may be arranged in the beam path between the second facet mirror 22 and the object field 5. The transfer optics unit may comprise exactly one mirror, or alternatively two or more mirrors arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In a further embodiment of the illumination optics unit 4, the deflection mirror 19 may also be omitted, and so the illumination optics unit 4 may have exactly two mirrors downstream of the collector 17 in that case, specifically the first facet mirror 20 and the second facet mirror 22.

The imaging of the first facets 21 into the object plane 6 via the second facets 23 or using the second facets 23 and a transfer optics unit is regularly only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optical unit. The penultimate mirror M5 and the last mirror M6 each have a passage opening for the illumination radiation 16. The projection optics unit 10 has an image-side numerical aperture that is greater than 0.5 and may also be greater than 0.6 and for example may be 0.7 or 0.75.

Reflection surfaces of the mirrors Mi may take the form of free-form surfaces without an axis of rotational symmetry. As an alternative, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings can be designed as multilayer coatings, for example with alternating layers of molybdenum and silicon.

The projection optics unit 10 has a large object-image shift in the y-direction between a y-coordinate of a center of the object field 5 and a y-coordinate of the center of the image field 11. In the y-direction, this object-image shift may be of approximately the same size as a z-distance between the object plane 6 and the image plane 12.

For example, the projection optics unit 10 may have an anamorphic design. For example, it has different imaging scales βₓ, β_{y} in the x- and y-directions. The two imaging scales βₓ, β_{y} of the projection optics unit 10 can be at (βₓ, β_{y})=(+/−0.25, +/−0.125). A positive imaging scale β means imaging without image inversion. A negative sign for the imaging scale β means imaging with image inversion.

The projection optics unit 10 thus leads to a reduction in size with a ratio of 4:1 in the x-direction, i.e. in a direction perpendicular to the scanning direction.

The projection optics unit 10 leads to a reduction in size of 8:1 in the y-direction, i.e. in the scanning direction.

Other imaging scales are also possible. Imaging scales with the same signs and the same absolute values in the x- and y-directions, for example with absolute values of 0.125 or 0.25, are also possible.

The number of intermediate image planes in the x-direction and in the y-direction in the beam path between the object field 5 and the image field 11 may be the same or can be different, depending on the embodiment of the projection optics unit 10. Examples of projection optics units with different numbers of such intermediate images in the x- and y-directions are known from US 2018/0074303 A1.

In each case, one of the pupil facets or second facets 23 is assigned to exactly one of the field facets 21 for the purpose of forming a respective illumination channel for illuminating the object field 5. For example, this may result in illumination according to the Kohler principle. The far field is decomposed into a plurality of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is for example of maximum homogeneity. It can have a uniformity error of less than 2%. Field uniformity can be achieved by overlaying different illumination channels.

The illumination of the entrance pupil of the projection optics unit 10 may be defined geometrically by way of an arrangement of the pupil facets. The intensity distribution in the entrance pupil of the projection optics unit 10 may be set by selecting the illumination channels, for example the subset of the pupil facets which guide light. This intensity distribution is also referred to as illumination setting or illumination pupil filling.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and, for example, of the entrance pupil of the projection optics unit 10 are described below.

The projection optics unit 10 may comprise for example a homocentric entrance pupil. The latter may be accessible. It may also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays, which is determined in pairs, becomes minimal. This area is the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical component of the transfer optics unit, should be provided between the second facet mirror 22 and the reticle 7. This optical element may be used to take into account the different poses of the tangential entrance pupil and the sagittal entrance pupil.

In the arrangement of the components of the illumination optics unit 4 illustrated in FIG. 1, the pupil facet mirror 22 is arranged in an area conjugate to the entrance pupil of the projection optics unit 10. The field facet mirror 20 is arranged at a tilt to the object plane 6. The first facet mirror 20 is arranged so as to be tilted with respect to an arrangement plane defined by the deflection mirror 19.

The first facet mirror 20 is arranged at a tilt to an arrangement plane defined by the second facet mirror 22.

Different embodiments of an actuatable mirror assembly 25, which may be part of the first facet mirror 20 and/or of the second facet mirror 22, are described below on the basis of FIG. 2 et seq. A Cartesian xyz-coordinate system is used in conjunction with these FIG. 2 et seq. in order to clarify positional relationships.

FIG. 2 shows a greatly enlarged axial section, parts of which are in detail, of a mirror assembly 25 of a micromirror or individual mirror 26 in the first facet mirror 20 and/or in the facet mirror 22.

The individual mirror 26 has a reflection surface 27 with an optical coating that is highly reflective for the illumination light 16. Above or below this optical coating, the mirror 26 has a stress coating for specifying a curvature profile of the reflection surface 27, which is depicted in FIG. 2 with an exaggerated small radius of curvature. In actual fact, the curvature is significantly less pronounced than what is illustrated in FIG. 2. The optical coating and the stress coating, neither of which are depicted in detail in the drawing, are carried by a mirror body 28 of the mirror 26.

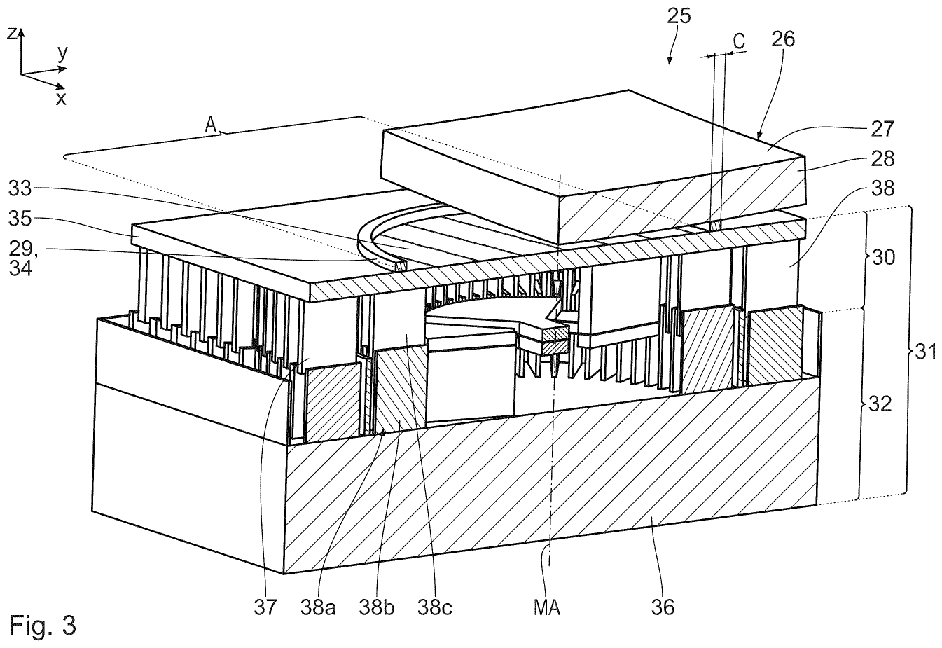

Using a bearing device 29 (cf. also FIG. 3), the mirror 26 is secured to an actuator mirror carrier unit 30, which is displaceable by an actuation mechanism, also referred to as a rotor and in turn part of an actuator apparatus 31 of the mirror assembly 25, which is also referred to as a MEMS unit. A bearing plane of the bearing device 29 runs parallel to the xy-plane.

The actuator apparatus 31 allows the mirror 26 to be tilted, especially about the tilt axes δx and/or δy.

In addition to the actuator mirror carrier unit 30, the actuator apparatus 31 also comprises a main actuator unit 32 that is fixed to the frame. The actuator units 30, 32 have transducers as actuators, which are reproduced schematically in FIG. 2, for example. The main actuator unit 32 is also referred to as a stator.

The mirror 26 is secured to the actuator-displaceable actuator mirror carrier unit 30 of the actuator apparatus 31 by way of the bearing device 29.

The bearing device 29 is embodied such that an enclosed securing region 33, which is provided by the bearing device and indicated by hatching in FIG. 3 and by which the mirror 26 is secured to the actuator mirror carrier unit 30, has an extent A between maximally spaced-apart securing points F_{P} of the bearing device 29 in the direction of a maximal securing distance, the extent being at least 25% of an extent B of the reflection surface 27 of the mirror 26 in the direction of the maximal securing distance.

The maximal securing distance, in the direction of which the extents A and B are illustrated in FIGS. 2 and 3, runs in the direction of the y-axis in FIGS. 2 and 3.

The bearing device 29 has the form of a circumferential bearing ring which represents a circumferential securing track 34 of the enclosed securing region 33. The enclosed securing region 33 represents an area delimited or enclosed by the securing track 34. The closed securing track 34 delimits 100% of the enclosed securing region 33 in the circumferential enclosing direction. Depending on the embodiment of the securing track, such a boundary of the securing region 33 in the circumferential enclosing direction made up by the securing track may also total less than 100%, but the latter delimits at least 50% of the enclosed securing region 33 in any case.

The securing track 34 and hence the bearing ring of the bearing device 29 runs in circular fashion between a support plate 35 of the actuator mirror carrier unit 30 and the mirror body 28. The bearing ring of the bearing device 29 is secured to these two components 35 and 28, for example via a bonding method such as e.g. adhesive bonding, eutectic bonding, diffusion bonding, welding or solder bonding or via an adhesive bond.

A base plate 36, by which the transducers of the main actuator unit 32 are carried, is part of the main actuator unit 32.

On account of the annular securing track 34, the extent A of the enclosed securing region 33 in the direction of the maximal securing distance represents the ring diameter of the securing track 34 at the same time. In a further embodiment of the bearing device, the securing track predetermined in this way may also have for example an elliptical or oval extent or a predetermined rectangular or polygonal extent. For example, the bearing device may also comprise multiple nested circumferential securing tracks 34ᵢ, which may extend concentrically for example.

The securing track formed by the bearing device 29 has a transverse extent C, i.e. a radial extent in the case of the circular securing track 34, which is less than one tenth of a longitudinal extent along the extent of the track of the securing track 34, i.e. less than one tenth of a circumference of the securing track 34. For example, this transverse extent is less than one tenth of a radius of the circular securing track 34.

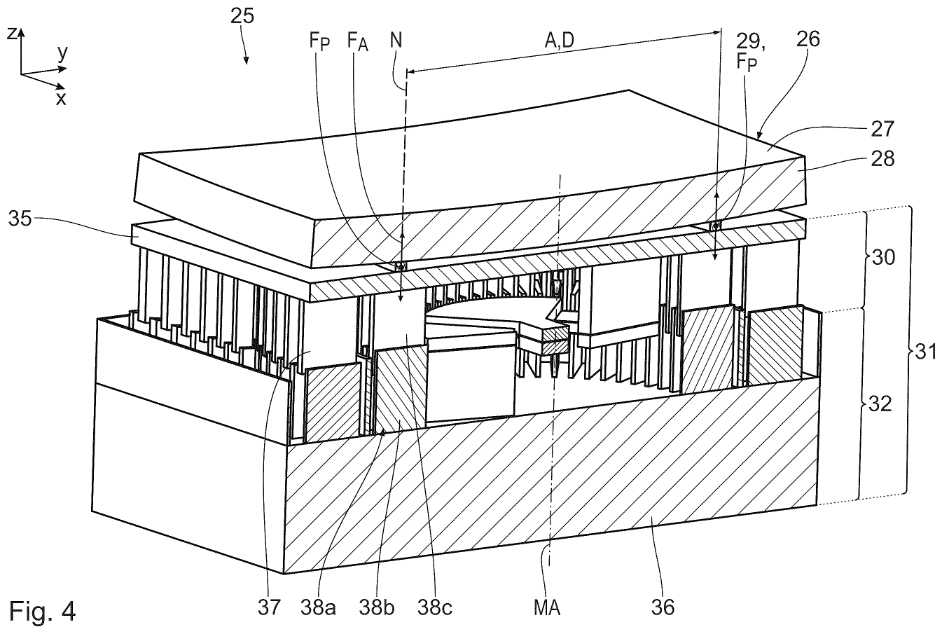

The securing region extent A is somewhat smaller than a distance between two actuator units 37, 38, for example between two transducers, of the actuator mirror carrier unit 30 of the actuator apparatus 30 (cf. FIG. 4). This leads to actuator forces F_{A}, which are indicated by double-headed arrows in FIG. 4, being introduced directly between the support plate 35 and the mirror body 28 by way of the bearing device 29. Detours in the force introduction paths from the respective actuator unit 37, 38 to the mirror unit 28 are avoided in that case.

The actuator units 37, 38 are tilt transducers for tilting the actuator mirror carrier unit 30 relative to the main actuator unit 32.

The mirror assembly 25 also comprises a sensor apparatus 38a, by which a displacement position of the actuator mirror carrier unit 30 relative to the main actuator unit 32 can be detected by a sensor mechanism. The sensor apparatus 38a has a main sensor component 38b and a sensor mirror carrier component 38c.

The main sensor component 38b is secured to the main actuator unit 32. The sensor mirror carrier component 38c is secured to the actuator mirror carrier unit 30. The sensor apparatus 38a operates capacitively, with comb structures of the sensor mirror carrier component 38c meshing with comb structures, which have a complementary shape, of the main sensor component 38b in the event of a corresponding displacement of the actuator mirror carrier unit 30 relative to the main actuator unit 32. In this respect, the sensor principle of the sensor apparatus 38a corresponds to a drive principle of the actuator apparatus 31. For example, the sensor mirror carrier component 38c is constructed with a plurality of sensor transducers, which are arranged radially within the tilt transducers 37, 38 of comparable structure in the actuator mirror carrier unit 30 and are secured to the support plate 35 of the actuator mirror carrier unit 30.

The securing region extent A (cf. FIG. 4) corresponds to a distance between two actuator units of the sensor mirror carrier component 38c. This leads to a displacement of the mirror body 28 with respect to the main sensor component 38b being imparted directly by way of the sensor mirror carrier component 38c, and so for example mechanical stress contributions of the mirror body 28 between securing points F_{P} of the enclosed securing region 33 of the bearing device 29 do not lead to any falsification of a sensor result from the sensor apparatus 38a. In FIG. 4, this is illustrated by the double-headed arrows of the actuator forces F_{A}.

The respective securing points F_{P} of the bearing device 29 are directly adjacent in the respective sensor mirror carrier component 38c, specifically as they are only spaced apart from the latter by the thickness of the support plate 35.

A normal N to the reflection surface 27 of the mirror 26 in the mirror assembly 25 that passes through the respective securing point of the enclosed securing region 33 also passes through the sensor mirror carrier component 38c, as likewise illustrated in FIG. 4.

The securing points F_{P} of the bearing device 29, which are located in the sectional plane of FIG. 4 and on the securing track 34, thus are arranged directly adjacent to the sensor mirror carrier component 38c.

In the embodiment according to FIG. 4, the securing region extent A is just as large as the distance D between central regions of the sensor transducers 38c. As a general rule:

$$0.7 D \leq A \leq 1.3 D .$$

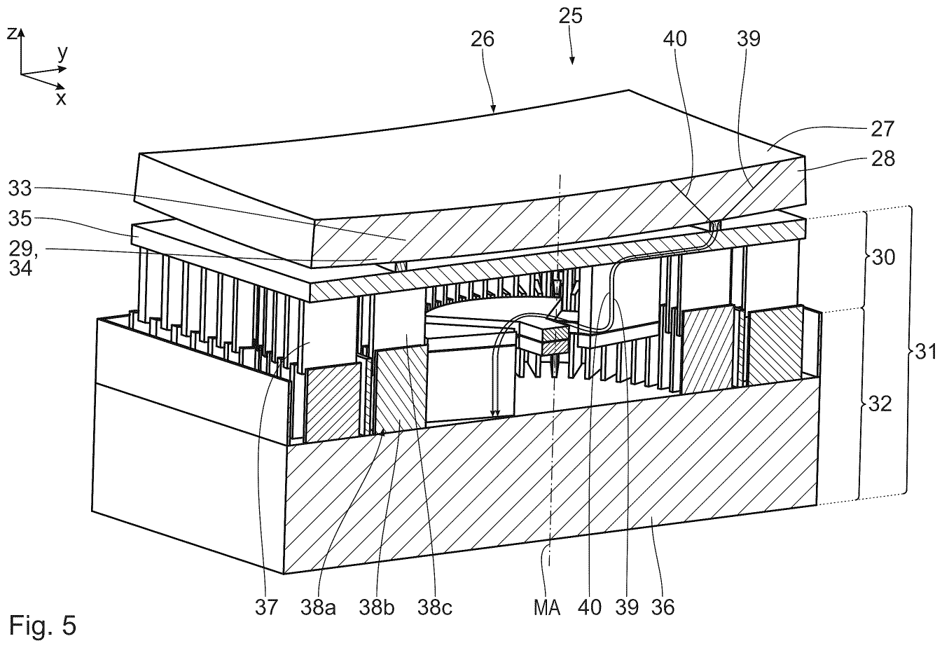

FIG. 5 illustrates an extent of two heat-conducting paths 39, 40, indicated by way of example, between the reflection surface 27 and the base plate 36 of the assembly 25. These heat-conducting paths 39, 40 run to the base plate 36 via the bearing device 29, the actuator mirror carrier unit 30 with the sensor mirror carrier component 38c and the main actuator unit 32. A corresponding path profile is comparatively short on account of the proportion of the enclosed securing region 33 integrated over the entire reflection surface 27 being comparatively large in comparison with the reflection surface 33, and so this results in a good heat transfer between the reflection surface 27 and the base plate 36. In that case, radiation absorbed by the respective mirror 26 during the operation of the projection exposure apparatus 1 does not lead to unwanted thermal deformations of the mirror body 28 or of the reflection surface 27. It is possible to minimize the temperature increase in the mirror.

A corresponding actuator or sensor transducer arrangement is described in WO 2016/146 541 A1.

On account of the rotational symmetry of the securing of the mirror body 28 to the support plate 35 about a central axis MA of the mirror 26, a symmetry of this securing by way of the bearing corresponds to a symmetry of the spherical curvature of the reflection surface 27 that is impressed on the mirror 26 by way of the stress coating.

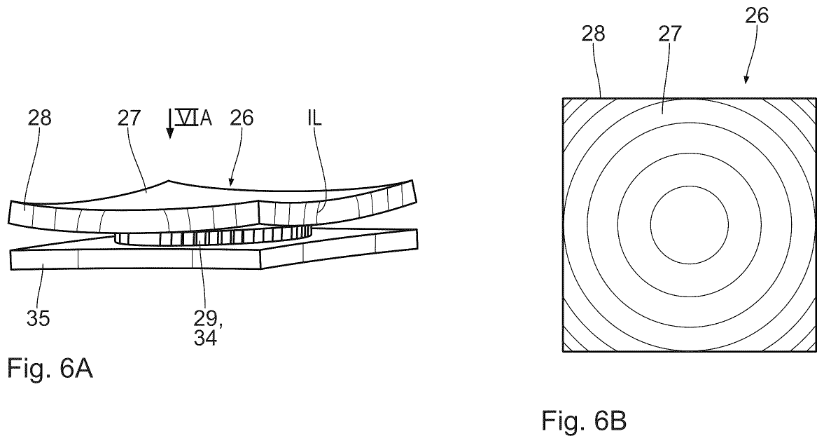

Once again in greatly exaggerated fashion, FIG. 6A illustrates these symmetry relationships in the event of a correspondingly concavely curved reflection surface 27.

The securing track 34 runs along a constant sagittal height of the reflection surface 27. This sagittal height is lower within the securing track 34 in the case of a concave design of the reflection surface 27, and the sagittal height of the reflection surface 27 is greater outside of the securing track 34. On account of the small transverse extent C of the securing track 34, a target curvature profile of the reflection surface 27, as impressed by way of the stress coating of this reflection surface 27, is only influenced to a very small extent.

FIGS. 6A and 6B illustrate exemplary iso-displacements IL of the mirror deformation produced by way of the stress coating in the mirror body 28.

In accordance with the rotationally symmetrically concavely curved reflection surface 27, these isolines IL extend in the form of circles that are concentric with respect to a center of the reflection surface 27.

The isolines IL in the plan view of the reflection surface 27 according to FIG. 6B exhibit the rotationally symmetrical spherical deformation of the mirror body.

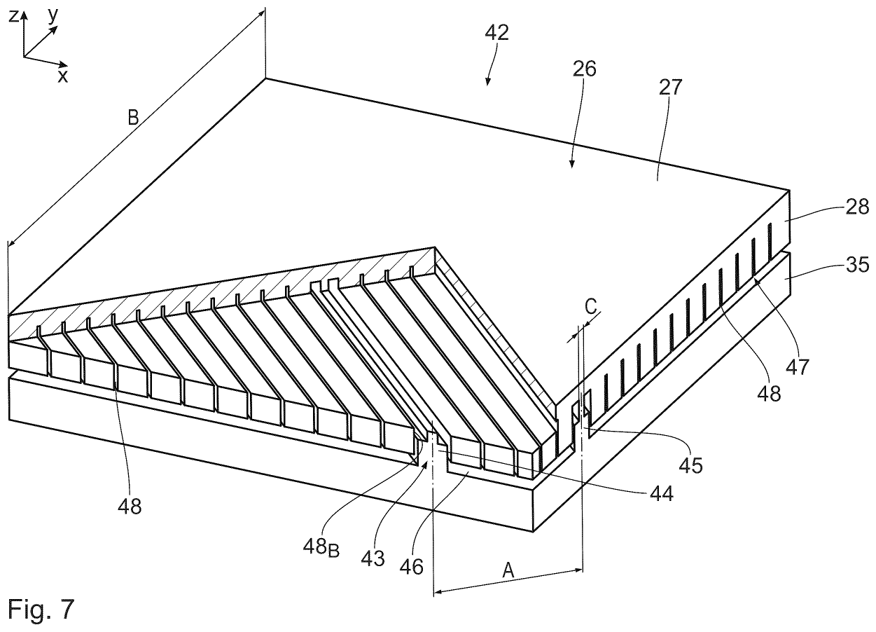

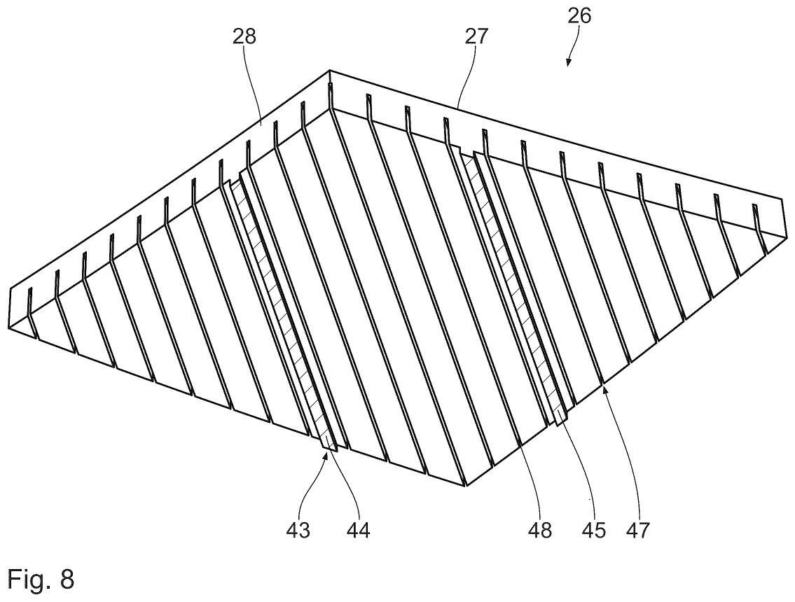

With reference to FIGS. 7 and 8, a description is given below of a further embodiment of an actuatable mirror assembly 42, which can be used instead of the mirror assembly 25. Components and functions that correspond to those which have already been explained above with reference to FIGS. 1 to 6, and for example with reference to FIGS. 2 to 6A, bear the same reference signs and will not be discussed again in detail. For example, a construction of a sensor apparatus of the mirror assembly 42 corresponds to that which has been described above in the context of the mirror assembly 25 (cf. the sensor apparatus 38a therein). This sensor apparatus is not illustrated for the mirror assembly 42.

The mirror assembly 42 is designed such that a concave or convex cylindrical mirror design of the mirror 26 results from an appropriate stress coating on the reflection surface 27.

A bearing device 43 of the mirror assembly 42, the bearing function of which corresponds to that of the bearing device 29 of the mirror assembly 25, comprises two bearing strips 44, 45 that have two spaced-apart securing tracks, which in turn form an enclosed securing region 46, indicated by dashed lines in FIG. 7, therebetween.

In the embodiment of the mirror assembly 42, the enclosed securing region 46 has an extent A between maximally spaced-apart securing points of the bearing device 43 in the direction of a maximal securing distance that runs parallel to the angle bisector of the coordinate axes x and y of the coordinate system, the extent being at least 15% of a typical extent B of the reflection surface 27 of the mirror 26. This extent A, i.e. the distance between the two bearing strips 44, 45, is smaller than a length L of the respective bearing strip 44, 45. Thus, it also holds true here that the securing tracks, i.e. the bearing strips 44, 45, delimit at least 50% of the securing region 46 enclosed thereby.

In FIG. 7, an edge length in the direction of the y-coordinate is illustrated as a typical extent B of the reflection surface 27. Alternatively, the typical extent B might for example be the mean value of the two edge lengths of the reflection surface 27, which is rectangular in this case. The typical extent of the reflection surface may also be measured in the direction of the maximal securing distance and then is the length of one diagonal of this reflection surface 27 in the case of the rectangular or square reflection surface 27 according to FIG. 7.

The two bearing strips 44, 45 and hence the two securing tracks of the mirror assembly 42 are designed as straight securing tracks, which are spaced apart from one another by the extent A in the direction of the maximal securing distance.

FIG. 8 shows, in an illustration obliquely from below and once again with exaggerated curvature, a cylindrical surface effect of the stress coating on the reflection surface 27 of the mirror body 28 of the mirror assembly 42 according to FIG. 7. The reflection surface 27 is curved concavely in the form of a cylinder between the horizontally most remote corners of the reflection surface in FIG. 8.

To a good approximation, the two bearing strips 44, 45 of the bearing device 43 run along constant sagittal height values of the reflection surface 27.

In the mirror assembly 42, the mirror body 28 has contouring 47 for specifying a cylinder curvature profile of the reflection surface 27, the contouring being found on the mirror body underside facing away from the reflection surface 27. The contouring 47 is formed by a plurality of equidistant, parallel grooves 48, which have been introduced into the underside of the mirror body 28 and the profile of which is visible in the partially broken section of the mirror body 28 of FIG. 7. The grooves 48 run parallel to the bearing strips 44, 45.

A groove 48_{B} that is wider than the other grooves has been introduced into the underside of the mirror body 28 in the region of the bearing strips 44, 45.

This forms a solid-state tilting flexure of the mirror body 28 which enables a deformation of the mirror body 28 and hence of the reflection surface 27 on account of a corresponding effect of the stress coating.

Corresponding contouring may also be present in the mirror body 28 of the mirror assembly 25, for example in the form of concentric circular or elliptical grooves.

In order to produce a microstructured component, for example a highly integrated semiconductor component, for example a memory chip, with the aid of the projection exposure apparatus 1, firstly the reticle 7 and the wafer 13 are provided. Subsequently, a structure on the reticle 7 is projected onto a light-sensitive layer on the wafer 13 using the projection optics unit 10 in the projection exposure apparatus 1. By developing the light-sensitive layer, a microstructure or nanostructure is then produced on the wafer 13 and the microstructured or nanostructured component is produced therefrom.

What is claimed is:

1. A mirror assembly, comprising:
an actuator apparatus, comprising:
a main actuator unit fixed to a frame; and
an actuator mirror carrier unit configured to be displaced by the main actuator unit;
a mirror comprising a reflection surface secured to the actuator mirror carrier unit; and
a bearing device configured to secure the mirror to the actuator mirror carrier unit,
wherein:
the bearing device provides an enclosed securing region having an extent between maximally spaced-apart securing points of the bearing device in a direction of a maximal securing distance on the actuator mirror carrier unit; and
the extent is at least 15% of a typical extent of the reflection surface of the mirror.

2. The mirror assembly of claim 1, further comprising a sensor device which comprises:
a main sensor component secured to the main actuator unit; and
a sensor mirror carrier component secured to the actuator mirror carrier unit,
wherein at least one of the securing points is directly adjacent to the sensor mirror carrier component.

3. The mirror assembly of claim 2, wherein the enclosed securing region comprises a circumferential securing track.

4. The mirror assembly of claim 3, wherein the securing track as a whole is directly adjacent to the sensor mirror carrier component.

5. The mirror assembly of claim 2, wherein the enclosed securing region comprises at least two spaced-apart securing tracks.

6. The mirror assembly of claim 5, wherein at least one of the spaced-apart securing tracks is a straight securing track.

7. The mirror assembly of claim 1, comprising a securing track, wherein the track has a first extent and a second extent transverse to the first extent, and the second extent is less than 10% of the first extent.

8. The mirror assembly of claim 1, wherein the extent of the enclosed securing region in the direction of the maximal securing distance corresponds to a distance between two actuator devices of the actuator apparatus.

9. The mirror assembly of claim 1, wherein the reflection surface of the mirror is concave or convex shape with respect to a direction of curvature, and the reflection surface of the mirror is spherical, toric or cylindrical with respect to a shape of curvature.

10. The mirror assembly of claim 1, wherein the mirror comprises a mirror body having a stress coating configured to generate a curvature profile of the reflection surface.

11. The mirror assembly of claim 1, wherein the mirror comprises a mirror body, an underside of the mirror body being contoured and/or structured to specify a curvature profile of the reflection surface.

12. The mirror assembly of claim 1, wherein the enclosed securing region comprises a circumferential securing track.

13. The mirror assembly of claim 12, wherein the securing track as a whole is directly adjacent to the sensor mirror carrier component.

14. The mirror assembly of claim 1, wherein the enclosed securing region comprises at least two spaced-apart securing tracks.

15. The mirror assembly of claim 14, wherein at least one of the spaced-apart securing tracks is a straight securing track.

16. The mirror assembly of claim 14, wherein the spaced-apart securing tracks are parallel to one another.

17. The mirror assembly of claim 13, wherein the spaced-apart securing tracks are parallel to one another.

18. A system, comprising:
a mirror assembly according to claim 1,
wherein the system is an optical system.

19. An apparatus, comprising:
an optical system comprising a mirror assembly according to claim 1,
wherein the apparatus is a projection exposure apparatus.

20. A method of using a projection exposure apparatus comprising an illumination optics unit and a projection optics unit, the method comprising:
using the illumination optics unit to illuminate an object in an object plane of the projection optics unit; and
using the projection optics unit to image the object into an image field of the projection optics unit,
the illumination optics unit comprises a mirror assembly according to claim 1.
